(19) United States
(12) Patent Application Publication
(10) Pub. No.: US 2010/0315120 A1
(43) Pub. Date: Dec. 16, 2010

(54) Dynamic adaptive terminal load adjusting method and circuit

(75) Inventors: Guosheng Wu, Chengdu (CN); Yong Quan, Chengdu (CN)

Correspondence Address: ZHEN ZHENG LU, 1730 HUNTINGTON DRIVE #304, DUARTE, CA, 91010, US

(73) Assignee: IPGoal Microelectronics (SiChuan) Co., Ltd.

(21) Appl. No.: 12/797,611

(22) Filed: Jun. 10, 2010

(30) Foreign Application Priority Data
Jun. 11, 2009 (CN) 200910059568.X

(51) Int. Cl. H03H 7/38

(52) U.S. Cl. 326/30

(57) ABSTRACT

A dynamic adaptive terminal load adjustment method includes comparing a voltage on an on-chip termination impedance driven by an on-chip current source with a voltage of a band gap reference circuit to get an optimal trimming parameter by an adaptive control mechanism, wherein the optimal trimming parameter is applied to a terminal by an output control circuit to have a feedback control. The present invention is on-chip so the cost is saved. The terminal is separated from the adjusting circuit, thus the present invention has a good dynamic performance. Compared with laser trimming, no expensive cost is needed in the present invention. The present invention saves an IO pin without an external device, has the good temperature characteristic and high resistance regulation accuracy. Furthermore, the adjusting circuit is separated from the terminal load circuit by high matching of relative resistance of CMOS process, thus reducing the adverse impact.

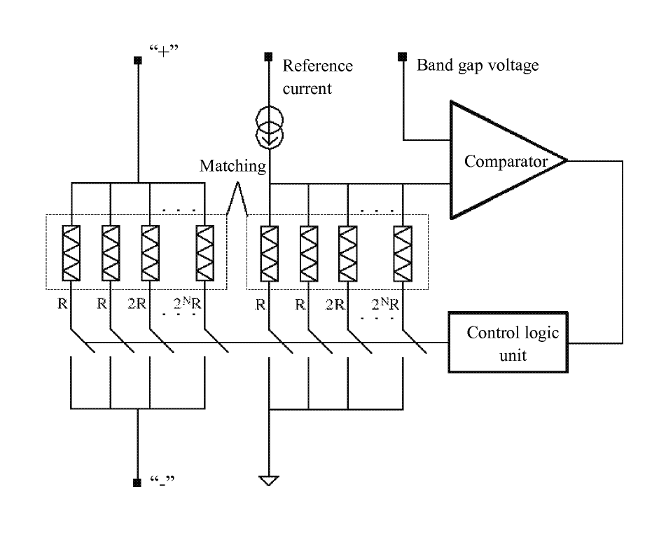

### BACKGROUND OF THE PRESENT INVENTION

1. Field of Invention

The present invention relates to a method and circuit for adjusting the terminal load by the on-chip band gap reference and reference current, and more particularly to a dynamic adaptive terminal load adjusting method and circuit.

2. Description of Related Arts

For a high-speed data transmission system, the impedance mismatching will cause signal reflections and affect signal quality, so the impedance mismatching between the transmitting terminal and the receiving terminal is very important. However, the deviation of the manufacturing process is an objective existence, so there is a need for the error caused by the manufacturing process to make an appropriate compensation.

The commonly used compensation methods include laser trimming, a method of regarding the parallel transistors as the equivalent compensating resistors, and a method of using the off-chip reference resistor. Laser trimming is the manufacturing process of positioning a bunch of focused coherent light on the workpiece under the control of the microcomputer, so that the film of trimmed part of the workpiece can be gasified removed to reach the required parameters or resistance. However, laser trimming has a higher manufacturing cost. The compensation method of using transistors mainly regards the transistor as an equivalent compensating resistor, and its disadvantage is poor temperature characteristics that the equivalent compensating resistor will change with the working environment (working voltage/temperature, etc.). The method of using off-chip reference resistor mainly regards the external precision resistor as a reference to trim the internal termination resistor, its disadvantage is the need for the additional output pin, and its accuracy depends on the accuracy of the external resistor.

### SUMMARY OF THE PRESENT INVENTION

An object of the present invention is to provide a dynamic adaptive terminal load adjusting method and circuit, which adopts N-stage parallel resistors and makes use of band-gap reference, automatic feedback and dynamic regulation to regulate the terminal impedance.

Accordingly, in order to accomplish the above object, the present invention provides a dynamic adaptive terminal load adjusting method, comprising the step of comparing a voltage on an on-chip termination impedance driven by an on-chip current source with a voltage of a band gap reference circuit to get an optimal trimming parameter by an adaptive control mechanism, wherein the optimal trimming parameter is applied to a terminal by an output control circuit to have a feedback control.

The step of comparing comprises:

(1) producing a band gap voltage by a band gap reference and simultaneously obtaining a reference current;

(2) producing a corresponding load voltage by passing the reference current through a feedback resistor array of a band gap reference circuit, obtaining a result by comparing the load voltage with the band gap voltage, and sending the result to a control logic unit; and

(3) increasing or decreasing equivalent resistances of the terminal resistor array and the feedback resistor array respectively by controlling the switch-on or switch-off of the terminal resistor array and the feedback resistor array by the control logic unit according to the polarity of the result, wherein the equivalent resistances are theoretically equal to an expected termination impedance, actually, they finally approach the expected termination impedance due to various errors; simultaneously, exactly matching the terminal resistor array and the feedback resistor array through a terminal load mirrors the feedback resistor array, wherein the switch on-off mode of the terminal resistor array is consistent with that of the regulated feedback resistor array, and the mirror terminal resistor array is known as the actual termination impedance, whereby the physical separation of the adjusting circuit and the terminal resistor is achieved to make a dynamic resistor compensation.

The dynamic adaptive terminal load adjustment method is achieved by a circuit comprising a terminal resistor array, a feedback resistor array, a switch array, a comparator and a control logic unit, wherein terminal switches connected with the terminal resistor array and feedback switches connected with the feedback resistor array share a control terminal. Two ends of the feedback resistor array are equivalent, wherein one end is connected with an input of the comparator and simultaneously connected with an internal current source output of a chip, the other end is connected to ground. The other input of the comparator is connected with a band gap voltage or an equal proportional voltage obtained by the band gap voltage. An input of the control logic unit is connected with an output of the comparator, and an output of the control logic unit is connected with an input of the switch array.

The feedback resistor array is completely separated from the terminal resistor array in the circuit. However, the feedback resistor array exactly matches the terminal resistor array in the physical design, namely, in the layout.

Every terminal resistor of the terminal resistor array is connected with a corresponding terminal switch of the switch array in series, and then the terminal resistors connected with the terminal switches in series respectively are connected with each other in parallel, thus forming a terminal load. Every feedback resistor of the feedback resistor array is connected with a corresponding feedback switch of the switch array in series, and then the feedback resistors connected with the feedback switches in series respectively are connected with each other in parallel, thus forming a feedback resistor, wherein the feedback switches are corresponding to the terminal switches respectively.

The present invention uses the Ohm law of U=I×R, the constant voltage can be obtained under the drive of the constant current and vice versa, thus the load resistance is constant. For example, under the drive of the reference current, the load resistance is gradually increased or decreased and accordingly the load voltage is compared with the band gap voltage. As a result, the load resistance will be changed till the load voltage is the same as the band gap voltage. Alternatively, under the drive of the band gap voltage, the load resistance is gradually increased or decreased and accordingly the load voltage is compared with the reference voltage. As a result, the load resistance will be changed till the load voltage is the same as the reference voltage.

The beneficial effects of the present invention are illustrated as follows.

The present invention mainly uses the on-chip band gap reference and reference current as the reference, adopts two parallel resistor arrays exactly matching with each other in the layout to trim one of the two parallel resistor arrays, the two parallel resistor arrays uses the same switch control. The resistor manufactured by process has the characteristics of small relative error and large absolute error, so the trimming resistor array can be separated from the actual terminal resistor without the loss of trimming accuracy. The trimming resistor array is separated from the actual terminal resistor in the connection, so the terminal can be dynamically adjusted in real time. The present invention is on-chip so the cost is saved. The terminal is separated from the adjusting circuit, thus the present invention has a good dynamic performance The temperature characteristic of the adjusting method of adopting the resistor array is better than that of the adjusting method of using the transistor array as the equivalent resistor. Furthermore, compared with laser trimming, no expensive cost is needed in the present invention. Furthermore, compared with the external reference resistor, the present invention saves an IO pin without an external device. The regulation accuracy of the present invention is mainly associated with the band gap reference (actually, the reference current is obtained from the band gap reference), and the band gap reference has a good temperature and voltage characteristics, simultaneously, small process variation can be achieved by good matching design, thus leading to high resistance regulation accuracy. In addition, the adjusting circuit is separated from the terminal load circuit by high matching of relative resistance of CMOS process, thus reducing the adverse impact.

These and other objectives, features, and advantages of the present invention will become apparent from the following detailed description, the accompanying drawings, and the appended claims.

### BRIEF DESCRIPTION OF THE DRAWINGS

The drawing is a schematic circuit diagram of a dynamic adaptive terminal load adjusting method and circuit according to a preferred embodiment of the present invention.

### DETAILED DESCRIPTION OF THE PREFERRED EMBODIMENT

A dynamic adaptive terminal load adjustment method according to a preferred embodiment of the present invention comprises the step of comparing a voltage on an on-chip termination impedance driven by an on-chip current source with a voltage of a band gap reference circuit to get an optimal trimming parameter by an adaptive control mechanism, wherein the optimal trimming parameter is applied to a terminal by an output control circuit to have a feedback control.

The step of comparing comprises:

(1) producing a band gap voltage by a band gap reference and simultaneously obtaining a reference current;

(2) producing a corresponding load voltage by passing the reference current through a feedback resistor array of a band gap reference circuit, obtaining a result by comparing the load voltage with the band gap voltage, and sending the result to a control logic unit; and

(3) increasing or decreasing equivalent resistances of the terminal resistor array and the feedback resistor array respectively by controlling the switch-on or switch-off of the terminal resistor array and the feedback resistor array by the control logic unit according to the polarity of the result, wherein the equivalent resistances are theoretically equal to an expected termination impedance, actually, they finally approach the expected termination impedance due to various errors; simultaneously, exactly matching the terminal resistor array and the feedback resistor array through a terminal load mirrors the feedback resistor array, wherein the switch on-off mode of the terminal resistor array is consistent with that of the regulated feedback resistor array, and the mirror terminal resistor array is known as the actual termination impedance.

Therefore, the physical separation of the adjusting circuit and the terminal resistor is achieved to make a dynamic resistor compensation.

Referring to the drawing, the dynamic adaptive terminal load adjustment method is achieved by a circuit comprising a terminal resistor array, a feedback resistor array, a switch array, a comparator and a control logic unit, wherein terminal switches connected with the terminal resistor array and feedback switches connected with the feedback resistor array share a control terminal. Two ends of the feedback resistor array are equivalent, wherein one end is connected with an input of the comparator and simultaneously connected with an internal current source output of a chip, the other end is connected to ground. The other input of the comparator is connected with a band gap voltage or an equal proportional voltage obtained by the band gap voltage. An input of the control logic unit is connected with an output of the comparator, and an output of the control logic unit is connected with an input of the switch array.

The feedback resistor array is completely separated from the terminal resistor array in the circuit. However, the feedback resistor array exactly matches the terminal resistor array in the physical design, namely, in the layout.

Every terminal resistor of the terminal resistor array is connected with a corresponding terminal switch of the switch array in series, and then the terminal resistors connected with the terminal switches in series respectively are connected with each other in parallel, thus forming a terminal load. Every feedback resistor of the feedback resistor array is connected with a corresponding feedback switch of the switch array in series, and then the feedback resistors connected with the feedback switches in series respectively are connected with each other in parallel, thus forming a feedback resistor, wherein the feedback switches are corresponding to the terminal switches respectively.

As shown in the drawing, the present invention adopts 0.5V band gap voltage and 10 mA reference current to drive the feedback resistor array. The control logic unit controls the feedback resistor by scanning point by point. The resistance of R is about 50Ω, and the total stage is 5 (namely, N=5), thus the adjustment range of the feedback resistor is from R/2.96875(16.7)Ω to 32R(1600)Ω, the adjustment accuracy thereof is Rx/32R (wherein Rx is current parallel equivalent resistance). If the terminal impedance is expected to 50Ω, then the adjustment accuracy will be 1/32. Therefore, it can be expected that the ideal error is 1/32/50=0.875%. To reduce power consumption, the regulation loop can be turned off after completing the regulation.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A dynamic adaptive terminal load adjustment method, comprising the step of comparing a voltage on an on-chip termination impedance driven by an on-chip current source with a voltage of a band gap reference circuit to get an optimal trimming parameter by an adaptive control mechanism, wherein the optimal trimming parameter is applied to a terminal by an output control circuit to have a feedback control.

2. The dynamic adaptive terminal load adjustment method, as recited in claim 1, wherein said step comprises:
(1) producing a band gap voltage by a band gap reference and simultaneously obtaining a reference current;
(2) producing a corresponding load voltage by passing the reference current through a feedback resistor array of a band gap reference circuit, obtaining a result by comparing the load voltage with the band gap voltage, and sending the result to a control logic unit; and
(3) increasing or decreasing equivalent resistances of the terminal resistor array and the feedback resistor array respectively by controlling a switch-on or switch-off of a terminal resistor array and the feedback resistor array by the control logic unit according to the polarity of the result, wherein the equivalent resistances are theoretically equal to an expected termination impedance, actually, they finally approach the expected termination impedance due to various errors; simultaneously, exactly matching the terminal resistor array and the feedback resistor array through a terminal load mirrors the feedback resistor array, wherein the switch on-off mode of the terminal resistor array is consistent with that of the regulated feedback resistor array, and the mirror terminal resistor array is known as the actual termination impedance,
whereby, the physical separation of the adjusting circuit and the terminal resistor is achieved to make a dynamic resistor compensation.

3. A dynamic adaptive terminal load adjustment circuit, comprising:
a comparator, wherein one input of said comparator is connected with a band gap voltage or an equal proportional voltage obtained by said band gap voltage;
a terminal resistor array comprising a plurality of terminal resistors;
a feedback resistor array comprising a plurality of feedback resistors, wherein two ends of said feedback resistor array are equivalent, one end is connected with the other input of said comparator and simultaneously connected with an internal current source output of a chip, the other end is connected to ground;
a switch array comprising a plurality of terminal switches and a plurality of feedback switches, wherein said terminal switches connected with said terminal resistor array and said feedback switches connected with said feedback resistor array share a control terminal; and
a control logic unit, wherein an input of said control logic unit is connected with an output of said comparator, and an output of said control logic unit is connected with an input of said switch array.

4. The dynamic adaptive terminal load adjustment circuit, as recited in claim 3, wherein said feedback resistor array exactly matches said terminal resistor array in the layout.

5. The dynamic adaptive terminal load adjustment circuit, as recited in claim 3, wherein each of said terminal resistors of said terminal resistor array is connected with one of said terminal switches of said switch array in series, and then said terminal resistors connected with said terminal switches in series respectively are connected with each other in parallel, thus forming a terminal load, wherein each of said feedback resistors of said feedback resistor array is connected with one of said feedback switches of said switch array in series, and then said feedback resistors connected with said feedback switches in series respectively are connected with each other in parallel, thus forming a feedback resistor, wherein said feedback switches are corresponding to said terminal switches respectively.

6. The dynamic adaptive terminal load adjustment circuit, as recited in claim 4, wherein each of said terminal resistors of said terminal resistor array is connected with one of said terminal switches of said switch array in series, and then said terminal resistors connected with said terminal switches in series respectively are connected with each other in parallel, thus forming a terminal load, wherein each of said feedback resistors of said feedback resistor array is connected with one of said feedback switches of said switch array in series, and then said feedback resistors connected with said feedback switches in series respectively are connected with each other in parallel, thus forming a feedback resistor, wherein said feedback switches are corresponding to said terminal switches respectively.
